(19) United States
(12) Patent Application Publication
(10) Pub. No.: US 2017/0052418 A1
(43) Pub. Date: Feb. 23, 2017

(54) ARRAY SUBSTRATE, MANUFACTURING METHOD THEREOF, LIQUID CRYSTAL DISPLAY PANEL AND DISPLAY DEVICE

(71) Applicant: BOE TECHNOLOGY GROUP CO., LTD., Beijing (CN)

(72) Inventors: Bin Zhang, Beijing (CN); Shi SHU, Beijing (CN); Seong Yeol YOO, Beijing (CN); Tingting ZHOU, Beijing (CN); Zhanfeng CAO, Beijing (CN)

(21) Appl. No.: 15/138,788

(22) Filed: Apr. 26, 2016

(30) Foreign Application Priority Data
Aug. 19, 2015 (CN) 201510511403.7

(51) Int. Cl. G02F 1/1362; G02F 1/1333; G02F 1/1368; G02F 1/1343; H01L 27/12; H01L 29/786

(52) U.S. Cl. CPC G02F 1/136227; H01L 27/1222; H01L 27/124; H01L 27/1285; H01L 29/78675; H01L 29/78633; G02F 1/1368; G02F 1/134309; G02F 1/133345; G02F 1/13439; G02F 2001/133357

(57) ABSTRACT

An array substrate, a manufacturing method thereof, a liquid crystal display panel and a display device are provided. The array substrate includes a base substrate, an active layer, a gate insulating layer and a gate electrode which are located on the base substrate; a first insulating layer, a source electrode, a second insulating layer and a pixel electrode which are stacked on the active layer, the gate insulating layer and the gate electrode, sequentially; and a first connecting part and a second connecting part arranged on a same layer with the pixel electrode; wherein, the first connecting part is electrically connected with the active layer and the source electrode, and the second connecting part is electrically connected with the active layer and the pixel electrode.

### TECHNICAL FIELD

Embodiments of the present disclosure relate to an array substrate, a manufacturing method thereof, a liquid crystal display panel and a display device.

### BACKGROUND

In an existing display device, a Liquid Crystal Display (LCD) has advantages such as low power consumption, high display quality, no electromagnetic radiation and wide application range and so on, which is an important display device at present.

In an array substrate of the existing LCD, there is typically included: a base substrate, a thin film transistor and a pixel electrode which are located on the base substrate. The thin film transistor includes a gate electrode, an active layer, a source electrode and a drain electrode. The thin film transistor is divided into two types: a top gate type and a bottom gate type; an array substrate having a thin film transistor of a top gate type is taken for example, and a fabrication process thereof includes steps of: firstly, forming a pattern of an active layer on a base substrate; then, forming a gate insulating layer; next, forming a pattern of a gate electrode on the gate insulating layer; then, depositing a first insulating layer, and forming a via hole passing through the first insulating layer by a patterning process; next, forming patterns of a source electrode and a drain electrode, the source electrode and the drain electrode being electrically connected with the active layer through the via hole passing the first insulating layer, respectively; then, depositing a second insulating layer, and forming a via hole passing the second insulating layer by a patterning process; finally, forming a pattern of a pixel electrode, the pixel electrode being electrically connected with the drain electrode through the via hole passing the second insulating layer.

In the fabrication process of the array substrate described above, totally six times of the patterning process are needed, so the fabrication process is relatively complex.

### SUMMARY

An embodiment of the present disclosure provides an array substrate, comprising: a base substrate, an active layer, a gate insulating layer and a gate electrode which are located on the base substrate; a first insulating layer, a source electrode, a second insulating layer and a pixel electrode which are sequentially stacked on the active layer, the gate insulating layer and the gate electrode; and a first connecting part and a second connecting part arranged on a same layer with the pixel electrode; wherein, the first connecting part is electrically connected with the active layer through a first via hole, the first connecting part is electrically connected with the source electrode through a second via hole, and the second connecting part is electrically connected with the active layer through a third via hole; the second connecting part is electrically connected with the pixel electrode, and both the second connecting part and the pixel electrode are insulated from the first connecting part.

Another embodiment of the present disclosure provides a liquid crystal display panel, comprising: an array substrate as mentioned above and a counter substrate arranged opposite to the array substrate, and a liquid crystal layer located between the array substrate and the opposed substrate.

Another embodiment of the present disclosure provides a display device, comprising: a liquid crystal display panel as mentioned above.

Still another embodiment of the present disclosure provides a manufacturing method of an array substrate, comprising: forming patterns including an active layer, a gate insulating layer and a gate electrode on a base substrate; forming a first insulating layer on the base substrate formed with the patterns of the active layer, the gate insulating layer and the gate electrode; forming a pattern including a source electrode on the first insulating layer; forming a second insulating layer on the base substrate formed with the pattern of the source electrode; forming a first via hole, a second via hole and a third via hole by using a patterning process; and forming patterns including a pixel electrode, a first connecting part and a second connecting part on the base substrate formed with the first via hole, the second via hole and the third via hole by using one patterning process; wherein, the first connecting part is electrically connected with the active layer through the first via hole, the first connecting part is electrically connected with the source electrode through the second via hole, and the second connecting part is electrically connected with the active layer through the third via hole, the second connecting part is electrically connected with the pixel electrode, and the second connecting part and the pixel electrode are insulated from the first connecting part.

### BRIEF DESCRIPTION OF THE DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 to FIG. 3 are structural schematic diagrams of an array substrate provided by an embodiment of the disclosure, respectively;

FIG. 4 to FIG. 6 are flowcharts of a manufacturing method of an array substrate provided by an embodiment of the present disclosure, respectively; and

FIG. 7a to FIG. 7k, FIG. 7m and FIG. 7n are structural schematic diagrams of a manufacturing method of an array substrate in Example I of the present disclosure after executing respective steps, respectively.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Shapes and thicknesses of respective film layers in the accompanying drawings do not reflect true proportions of an array substrate, but only aim to illustrate content of the present disclosure.

An embodiment of the present disclosure provides an array substrate, as illustrated in FIG. 1, including: a base substrate 1, an active layer 2, a gate insulating layer 3 and a gate electrode 4 which are located on the base substrate 1, and a first insulating layer 5, a source electrode 6, a second insulating layer 7 and a pixel electrode 8 which are stacked on the active layer 2, the gate insulating layer 3 and the gate electrode 4, sequentially.

The array substrate further includes a first connecting part 9 and a second connecting part 10 which are arranged on the same layer with the pixel electrode 8. The first connecting part 9 is electrically connected with the active layer 2 through a first via hole A, the first connecting part 9 is electrically connected with the source electrode 6 through a second via hole B, and the second connecting part 10 is electrically connected with the active layer 2 through a third via hole C. The second connecting part 10 is electrically connected with the pixel electrode 8, and both the second connecting part 10 and the pixel electrode 8 are insulated from the first connecting part 9.

In the array substrate provided by the embodiment of the present disclosure, in a manufacturing method, after forming a first insulating layer, before forming a source electrode, it is not necessary to form a via hole for electrically connecting the source electrode with the active layer by performing a patterning process; but after forming a second insulating layer, and before forming a pixel electrode, a first via hole, a second via hole and a third via hole are formed by performing one patterning process, to expose the source electrode and the active layer; the source electrode and the active layer are electrically connected by using a first connecting part arranged on the same layer with the pixel electrode and insulated from the pixel electrode, a second connecting part arranged on the same layer with the pixel electrode and electrically connected with the pixel electrode is used as a drain electrode, and is electrically connected with the active layer through the third via hole, and in this way, as compared with an existing manufacturing method of an array substrate, one time of patterning process may be reduced, the fabrication process of the array substrate may be also simplified, and moreover, an arrangement of the drain electrode may be saved, so that an aperture ratio of the array substrate may be increased.

In the array substrate provided by the embodiment of the present disclosure, a thin film transistor may be of a bottom gate type structure, that is, a layer where a gate electrode is located is located between a base substrate and a gate insulating layer, and the gate insulating layer is located between the layer where the gate electrode is located and a layer where the active layer is located. Or, as illustrated in FIG. 1, a thin film transistor may further be of a top gate type structure, that is, the layer where the active layer 2 is located is located between the base substrate 1 and the gate insulating layer 3, and the gate insulating layer 3 is located between the layer where the active layer 2 is located and the layer where the gate electrode 4 is located, which is not limited here. It should be noted that, a thin film transistor of a top gate type structure is particularly applicable to fabricating a high-resolution liquid crystal display panel. The following embodiments given by the present disclosure are described by taking an array substrate having a thin film transistor of a top gate type structure for example.

In the array substrate provided by the embodiment of the present disclosure, the thin film transistor is of a top gate type structure, that is, the layer where the active layer is located is located between the base substrate and the gate insulating layer, and the gate insulating layer is located between the layer where the active layer is located and the layer where the gate electrode is located; as illustrated in FIG. 1, the first via hole A passes through the second insulating layer 7, the first insulating layer 5 and the gate insulating layer 3, and is located in a region of the active layer 2 close to the source electrode 6; the second via hole B passes through the second insulating layer 7, and is located directly above the source electrode 6; and the third via hole C passes through the second insulating layer 7, the first insulating layer 5 and the gate insulating layer 3, and is located in a region of the active layer 2 close to the pixel electrode 8; and in this way, the source electrode 6 and the active layer 2 may be electrically connected by a first connecting part 9 arranged on the same layer with the pixel electrode 8 and insulated from the pixel electrode 8 through the first via hole A and the second via hole B, the second connecting part 10 arranged on the same layer with the pixel electrode 8 and electrically connected with the pixel electrode 8 may be used as a drain electrode, and electrically connected with the active layer 2 through the third via hole C.

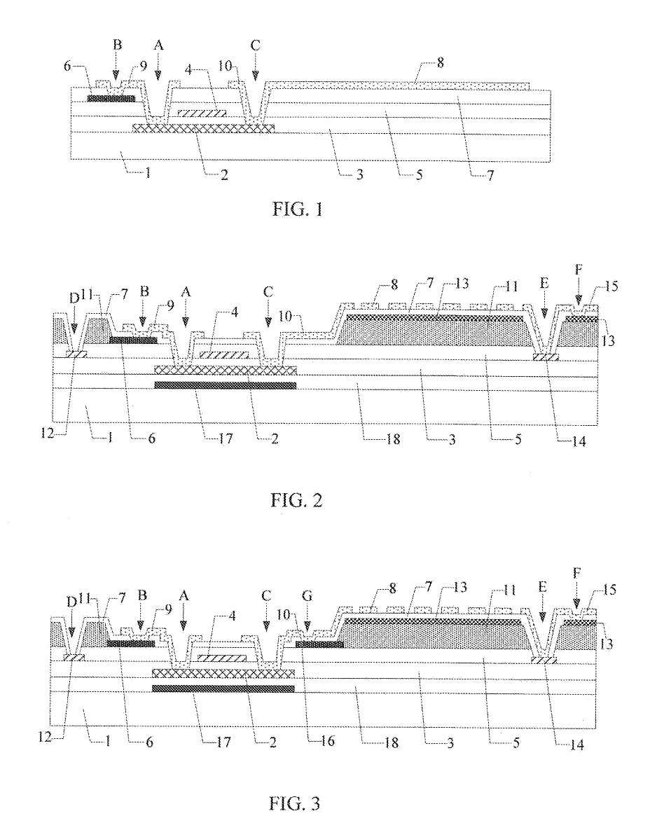

For example, as illustrated in FIG. 1 or FIG. 2, in a cross-section passing the first via hole, the third via hole and the gate electrode, the first via hole and the third via hole are located on both sides of the gate electrode, respectively.

For example, the second connecting part and the pixel electrode are formed integrally. Therefore, the second connecting part may be made of a material the same as that of the pixel electrode, for example, may be made of a transparent metal oxide material.

For example, as illustrated in FIG. 1 or FIG. 2, the first connecting part and the second connecting part are in direct contact with the active layer.

The array substrate provided by the embodiment of the present disclosure, as illustrated in FIG. 2, may further include: a planarization layer 11 located between the layer where the source electrode 6 is located and the second insulating layer 7; at least a region of the planarization layer 11 corresponding to the first connecting part 9 and the second connecting part 10 is a hollowed-out region, so as to facilitate the source electrode 6 being electrically connected with the active layer 2 by the first connecting part 9, and the second connecting part 10 being connected with the active layer 2; and respective layers on the array substrate may be flattened by the planarization layer 11, to provide a flat interface for forming a pixel electrode 8 in follow-up steps.

In some examples, both a gate line in the array substrate and a first wiring terminal electrically connected with the gate line are arranged on the same layer with the gate electrode, and both a date line in the array substrate and a second wiring terminal electrically connected with the data line are arranged on the same layer with the source electrode and the drain electrode, and therefore, the array substrate provided by the embodiment of the present disclosure, as illustrated in FIG. 2, may further include: a fourth via hole D which passes through the second insulating layer 7, the planarization layer 11 and the first insulating layer 5 and is located directly above a first wiring terminal 12 electrically connected with a gate line, and a fifth via hole which passes through the second insulating layer and the planarization layer and is located directly above a second wiring terminal electrically connected with a data line; and in this way, a Printed Circuit Board (PCB) may be bonded with the first wiring terminal 12 through the fourth via hole D, and bonded with the second wiring terminal through the fifth via hole.

The array substrate provided by the embodiment of the present disclosure may be applied to liquid crystal display panels of an Advanced Super Dimension Switch (ADS) type and an In-Plane Switch (IPS) type, that is, the array substrate provided by the embodiment of the present disclosure, as illustrated in FIG. 2, further includes: a common electrode 13 located between the planarization layer 11 and the second insulating layer 7; or, the array substrate provided by the embodiment of the present disclosure may be further applied to a liquid crystal display panel of a Twisted Nematic (TN) type, that is, the common electrode is located on a side of a counter substrate arranged opposite to the array substrate, which is not limited here.

When the array substrate provided by the embodiment of the present disclosure is applied to the liquid crystal display panels of the ADS type and the IPS type, as illustrated in FIG. 2, a common electrode line 14 electrically connected with the common electrode 13 is usually arranged on the same layer with the gate electrode 4; and therefore, the array substrate provided by the embodiment of the present disclosure, as illustrated in FIG. 2, may further include: a third connecting part 15 arranged on the same layer with the pixel electrode 8 and insulated from the pixel electrode; wherein, the third connecting part 15 is electrically connected with the common electrode line 14 through a sixth via hole E, the third connecting part 15 is electrically connected with the common electrode 13 through a seventh via hole F, the sixth via hole E passing through the second insulating layer 7, the planarization layer 11 and the first insulating layer 5 and being located direclty above the common electrode line 14, and the seventh via hole F passing through the second insulating layer 7 and being located directly above the common electrode 13; and in this way, the common electrode 13 and the common electrode line 14 may be electrically connected by using the third connecting part 15.

Of course, the common electrode line electrically connected with the common electrode may be further arranged on the same layer with the common electrode, which is not limited here.

In the array substrate provided by the embodiment of the present disclosure, besides a structure as illustrated in FIG. 1 and FIG. 2 that the second connecting part 10 is used as a drain electrode to be electrically connected with the active layer 2 and the pixel electrode 8 respectively, the array substrate provided by the embodiment of the present disclosure, as illustrated in FIG. 3, may further include: a drain electrode 16 arranged on the same layer with the source electrode 6, and an eighth via hole G which passes through the second insulating layer 7 and is located direclty above the drain electrode 16; wherein, the second connecting part 10 is electrically connected with the drain electrode 16 through the eighth via hole G; and in this way, the drain electrode 16 may be electrically connected with the active layer 2 and the pixel electrode 8 by using the second connecting part 10, respectively.

It should be noted that, when a thin film transistor in the array substrate provided by the embodiment of the present disclosure is of a top gate structure, as illustrated in FIG. 2 and FIG. 3, a light shielding layer 17 may be further arranged between a substrate 1 and the layer where the active layer 2 is located; the light shielding layer 17 may at least shield the active layer 2 without affecting normal display of a display panel, and the light shielding layer 17 may prevent light emitted by a backlight source from irradiating the active layer 2, so that a problem of too great leakage current of the thin film transistor may be avoided; and moreover, a buffer layer 18 may be further arranged between the light shielding layer 17 and the layer where the active layer 2 is located, and especially for the active layer 2 made of a polycrystalline silicon material, when performing an excimer laser annealing process on an active layer thin film made of an amorphous silicon material, the buffer layer 18 may prevent the active layer thin film from adverse effects caused by the base substrate 1 made of glass.

An embodiment of the present disclosure further provides a liquid crystal display panel, including: the above-described array substrate provided by the embodiment of the present disclosure and a counter substrate arranged opposite to the array substrate, and a liquid crystal layer located between the array substrate and the opposed substrate. For implementation of the liquid crystal display panel, the embodiment of the above-described array substrate may be referred to, and repeated sessions will not be illustrated here.

An embodiment of the present disclosure further provides a display device, including the above-described liquid crystal display panel provided by the embodiment of the present disclosure, and the display device may be: a mobile phone, a tablet personal computer, a television, a monitor, a laptop computer, a digital photo frame, a navigator, or any other product or part having a display function. For implementation of the display device, the embodiment of the above-described liquid crystal display panel may be referred to, and repeated sessions will not be illustrated here.

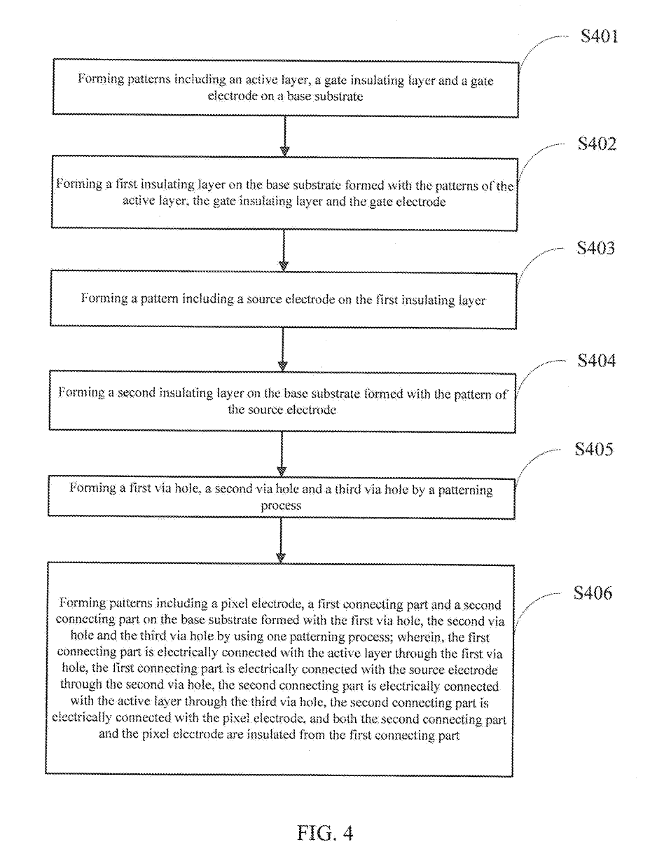

An embodiment of the present disclosure further provides a manufacturing method of an array substrate, as illustrated in FIG. 4, including the following steps.

S401: forming patterns including an active layer, a gate insulating layer and a gate electrode on a base substrate;

S402: forming a first insulating layer on the base substrate formed with the patterns of the active layer, the gate insulating layer and the gate electrode;

S403: forming a pattern including a source electrode on the first insulating layer;

S404: forming a second insulating layer on the base substrate formed with the pattern of the source electrode;

S405: forming a first via hole, a second via hole and a third via hole by using a patterning process; wherein, a first connecting part to be formed is electrically connected with an active layer through the first via hole, the first connecting part is electrically connected with a source electrode through the second via hole, and a second connecting part to be formed is electrically connected with an active layer through the third via hole.

S406: forming patterns including a pixel electrode, a first connecting part and a second connecting part on the base substrate formed with the first via hole, the second via hole and the third via hole by using one patterning process; wherein, the second connecting part is electrically connected with the pixel electrode, and both the second connecting part and the pixel electrode are insulated from the first connecting part.

In the manufacturing method of the array substrate provided by the embodiment of the present disclosure, after forming the first insulating layer, and before forming the source electrode, it is not necessary to form a via hole for electrically connecting the source electrode with the active layer by performing a patterning process; but after forming the second insulating layer, and before forming the pixel electrode, the first via hole, the second via hole and the third via hole are formed by performing one patterning process, to expose the source electrode and the active layer; the source electrode and the active layer are electrically connected by using the first connecting part arranged on the same layer with the pixel electrode and insulated from the pixel electrode, the second connecting part arranged on the same layer with the pixel electrode and electrically connected with the pixel electrode is used as the drain electrode, and is electrically connected with the active layer through the third via hole, and in this way, as compared with an existing manufacturing method of an array substrate, one time of the patterning process may be reduced, the fabrication process of the array substrate may be simplified, and moreover, an arrangement of the drain electrode may be saved, so that an aperture ratio of the array substrate may be increased.

At the time of forming a first via hole, a second via hole and a third via hole, a nornal mask may be used. For example, the source electrode and the active layer may be used as etch stop layers for the first via hole, the second via hole and the third via hole. At this moment, any suitable wet or dry etching may be selected according to materials of the source electrode and the active layer. Of course, the first via hole, the second via hole and the third via hole may be also fabricated by using any other patterning process.

The method provided by the embodiment of the present disclosure may be applied to fabricating an array substrate having a thin film transistor of a top gate structure, that is, when patterns including an active layer, a gate insulating layer and a gate electrode are formed on a base substrate by performing step S401 in the method provided by the embodiment of the present disclosure, for example, an active layer, a gate insulating layer and a gate electrode may be formed on a base substrate, sequentially. In some examples, firstly, a pattern including an active layer is formed on a base substrate, then, a gate insulating layer is formed on the base substrate formed with the pattern of the active layer, and finally, a pattern including a gate electrode is formed on the gate insulating layer; or, the method provided by the embodiment of the present disclosure may be applied to fabricating an array substrate having a thin film transistor of a bottom gate structure, that is, when patterns including an active layer, a gate insulating layer and a gate electrode are formed on a base substrate by performing step S401 in the method provided by the embodiment of the present disclosure, for example, a gate electrode, a gate insulating layer and an active layer may be formed on a base substrate, sequentially. In some examples, firstly, a pattern including a gate electrode is formed on a base substrate, then, a gate insulating layer is formed on the base substrate formed with the pattern of the gate electrode, and finally, a pattern including an active layer is formed on the gate insulating layer, which is not limited here. It should be noted that, a thin film transistor of a top gate type structure is particularly applicable to fabricating a high-resolution liquid crystal display panel. The following embodiments given by the present disclosure are described by taking an array substrate having a thin film transistor of a top gate type structure for example.

Taking an example that the active layer is made of a polycrystalline silicon material, step S401 in the method provided by the embodiment of the present disclosure, the forming patterns including an active layer, a gate insulating layer and a gate electrode, may be implemented in manners of: firstly, forming an active layer thin film by using an amorphous silicon material, and performing an excimer laser annealing process on the active layer thin film; then, patterning the active layer thin film processed by the excimer laser annealing process to form a pattern of the active layer; next, forming a gate insulating layer; then, forming a pattern of a gate electrode on the gate insulating layer, and reserving photoresist located directly above the pattern of the gate electrode; next, performing an N type heavily doping process on the amorphous silicon material by using the photoresist as a mask; and then, etching the photoresist, and performing an N type light doping process on the amorphous silicon material by using the etched photoresist as a mask. The amorphous silicon material may become a conductor by performing the N type heavily doping process on the amorphous silicon material, and a leakage current of the thin film transistor may be reduced by performing the N type light doping process on the amorphous silicon material.

Of course, in the method provided by the embodiment of the present disclosure, the active layer may be made of an oxide material, and a fabrication process thereof is similar to that of forming an active layer by using the oxide material in the related art, which will not be repeated here.

When the method provided by the embodiment of the present disclosure is applied to fabricating an array substrate having a thin film transistor of a top gate structure, that is, when, step S401 in the method provided by the embodiment of the present disclosure, forming patterns including the active layer, the gate insulating layer and the gate electrode on the base substrate, is specifically implemented in a manner of sequentially forming patterns including the active layer, the gate insulating layer and the gate electrode on the base substrate, forming the first via hole, the second via hole and the third via hole by performing step S405 in the method provided by the embodiment of the present disclosure, for example, may be implemented in manners of: forming the first via hole which passes through the second insulating layer, the first insulating layer and the gate insulating layer and is located in a region of the active layer close to the source electrode, forming the second via hole which passes through the second insulating layer and is located directly above the source electrode, and forming the third via hole which passes through the second insulating layer, the first insulating layer and the gate insulating layer and is located in a region of the active layer close to the pixel electrode; and in this way, after patterns including the pixel electrode, the first connecting part and the second connecting part are formed by performing step S406 in the method provided by the embodiment of the present disclosure in follow-up steps, the source electrode and the active layer may be electrically connected by the first connecting part through the first via hole and the second via hole, and the second connecting part is used as a drain electrode to be electrically connected with the active layer through the third via hole.

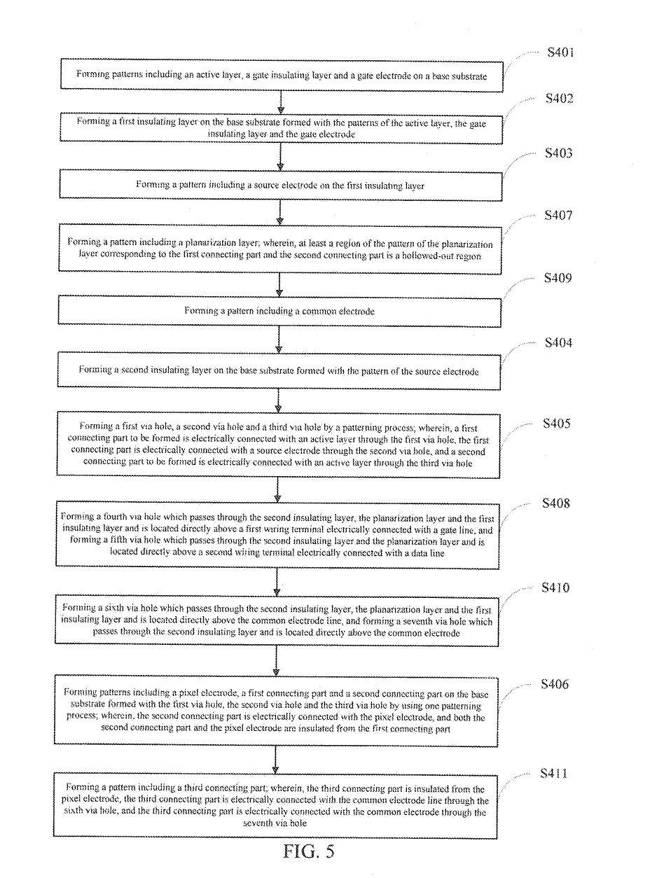

For example, after the pattern including the source electrode is formed by performing step S403 in the method provided by the embodiment of the present disclosure, before the second insulating layer is formed by performing step S404 in the method provided by the embodiment of the present disclosure, as illustrated in FIG. 5, the method further includes a step of:

S407: forming a pattern including a planarization layer; wherein, at least a region of the pattern of the planarization layer corresponding to the first connecting part and the second connecting part is a hollowed-out region; and in this way, it is convenient for electrically connecting the source electrode with the active layer by the first connecting part, and for electrically connecting the second connecting part with the active layer; and moreover, respective layers on the array substrate may be flattened by the planarization layer, to provide a flat interface for forming a pixel electrode in follow-up steps.

For example, both the gate line in the array substrate and the first wiring terminal electrically connected with the gate line are arranged on the same layer with the gate electrode, and both the date line in the array substrate and the second wiring terminal electrically connected with the data line are arranged on the same layer with the source electrode and the drain electrode, and therefore, while the first via hole, the second via hole and the third via hole are formed by performing step S405 in the method provided by the embodiment of the present disclosure, as illustrated in FIG. 5, the method may further comprise a step of:

S408: forming a fourth via hole which passes through the second insulating layer, the planarization layer and the first insulating layer and is located directly above the first wiring terminal electrically connected with the gate line, and forming a fifth via hole which passes through the second insulating layer and the planarization layer and is located directly above the second wiring terminal electrically connected with the data line; and in this way, a PCB may be bonded with the first wiring terminal through the fourth via hole, and bonded with the second wiring terminal through the fifth via hole.

The array substrate fabricated by the method provided by the embodiment of the present disclosure may be applied to liquid crystal display panels of an ADS type and an IPS type, that is, after the pattern including the planarization layer is formed by performing step S407 in the method provided by the embodiment of the present disclosure, before the second insulating layer is formed by performing step S404 in the method provided by the embodiment of the present disclosure, as illustrated in FIG. 5, the method may further include a step of:

S409: forming a pattern including a common electrode.

Of course, the array substrate fabricated by the method provided by the embodiment of the present disclosure may be applied to a liquid crystal display panel of a TN type, which is not limited here.

For example, when the array substrate fabricated by the method provided by the embodiment of the present disclosure is applied to liquid crystal display panels of an ADS type and an IPS type, a common electrode line electrically connected with the common electrode is usually arranged on the same layer with the gate electrode; and therefore, while the first via hole, the second via hole and the third via hole are formed by performing step S405 in the method provided by the embodiment of the present disclosure, as illustrated in FIG. 5, the method may further include a step of:

S410: forming a sixth via hole which passes through the second insulating layer, the planarization layer and the first insulating layer and is located directly above the common electrode line, and forming a seventh via hole which passes through the second insulating layer and is located directly above the common electrode.

While the pattern of the pixel electrode is formed by performing step S406 in the method provided by the embodiment of the present disclosure, as illustrated in FIG. 5, the method may further include a step of:

S411: forming a pattern including a third connecting part; wherein, the third connecting part is insulated from the pixel electrode, the third connecting part is electrically connected with the common electrode line through the sixth via hole, and the third connecting part is electrically connected with the common electrode through the seventh via hole; and in this way, the common electrode and the common electrode line may be electrically connected by using the third connecting part.

Of course, the common electrode line electrically connected with the common electrode may be further arranged on the same layer with the common electrode, which is not limited here.

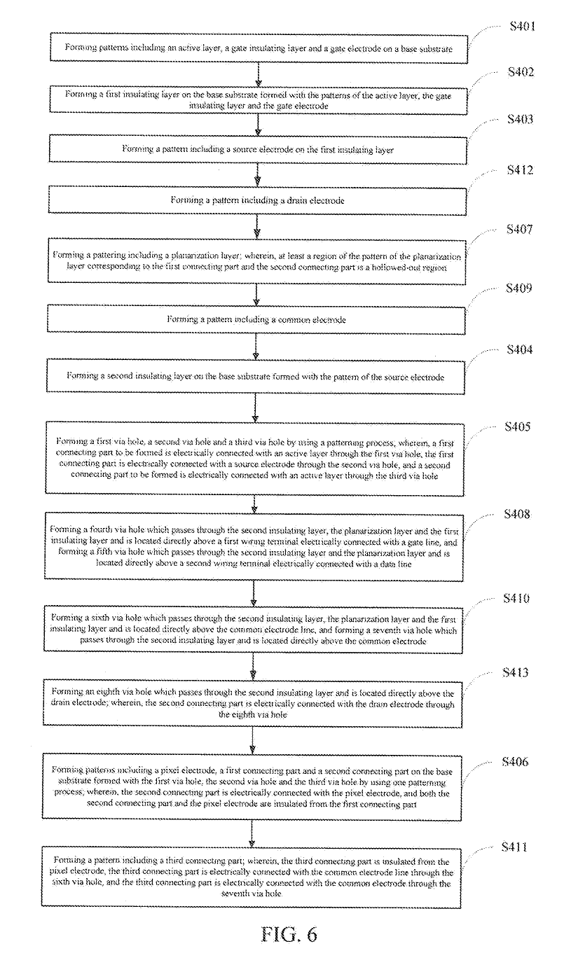

For example, while the pattern of the source electrode is formed by performing step S403 in the method provided by the embodiment of the present disclosure, as illustrated in FIG. 6, the method may further include a step of:

S412: forming a pattern including a drain electrode;

While the first via hole, the second via hole and the third via hole are formed by performing step S405 in the method provided by the embodiment of the present disclosure, as illustrated in FIG. 6, the method may further include a step of:

S413: forming an eighth via hole which passes through the second insulating layer and is located directly above the drain electrode; wherein, the second connecting part is electrically connected with the drain electrode through the eighth via hole; and in this way, the drain electrode 16 may be electrically connected with the active layer 2 and the pixel electrode 8 by using the second connecting part 10, respectively.

It should be noted that, when the method provided by the embodiment of the present disclosure is applied to fabricating an array substrate having a thin film transistor of a top gate structure, before patterns including the active layer, the gate insulating layer and the gate electrode are formed on the base substrate by performing step S401 in the method provided by the embodiment of the present disclosure, a pattern of a light shielding layer may be further formed on the base substrate; the pattern of the light shielding layer may at least shield the pattern of the active layer without affecting normal display of a display panel, and the light shielding layer may prevent light emitted by a backlight source from irradiating the pattern of the active layer, so that a problem of too great leakage current of the thin film transistor may be avoided; and moreover, after forming the pattern of the light shielding layer, and before forming the pattern of the active layer, a buffer layer may be further formed, and especially for the active layer made of a polycrystalline silicon material, when performing an excimer laser annealing process on the active layer thin film made of an amorphous silicon material, the buffer layer may prevent the active layer thin film from adverse affects caused by the base substrate made of glass.

Hereinafter, the method provided by the embodiment of the present disclosure is applied to fabricating the array substrate illustrated in FIG. 2 is described by a specific example in detail.

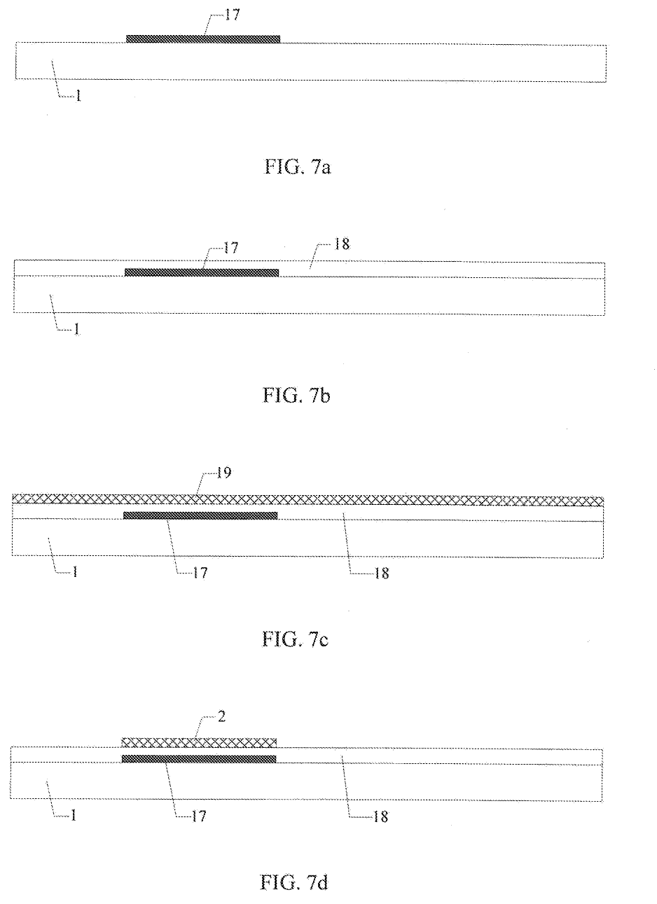

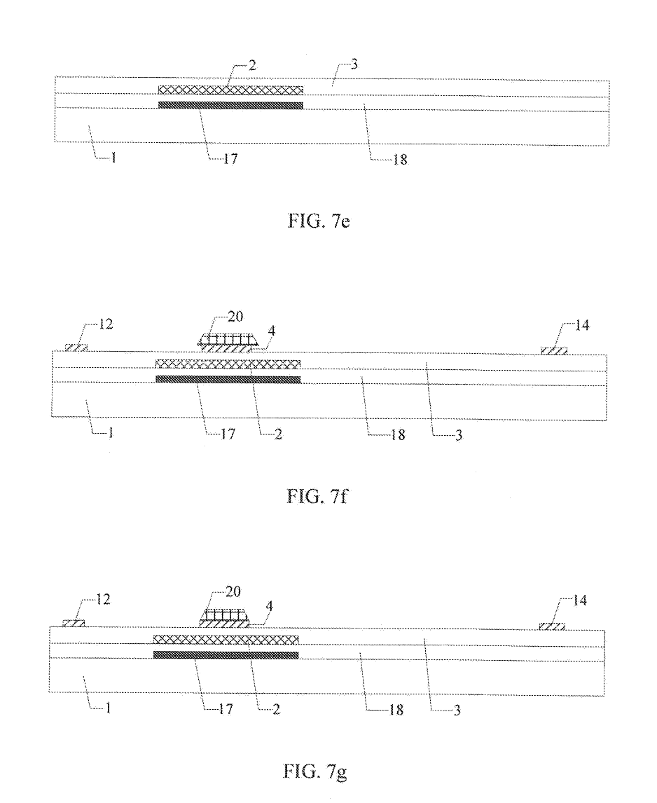

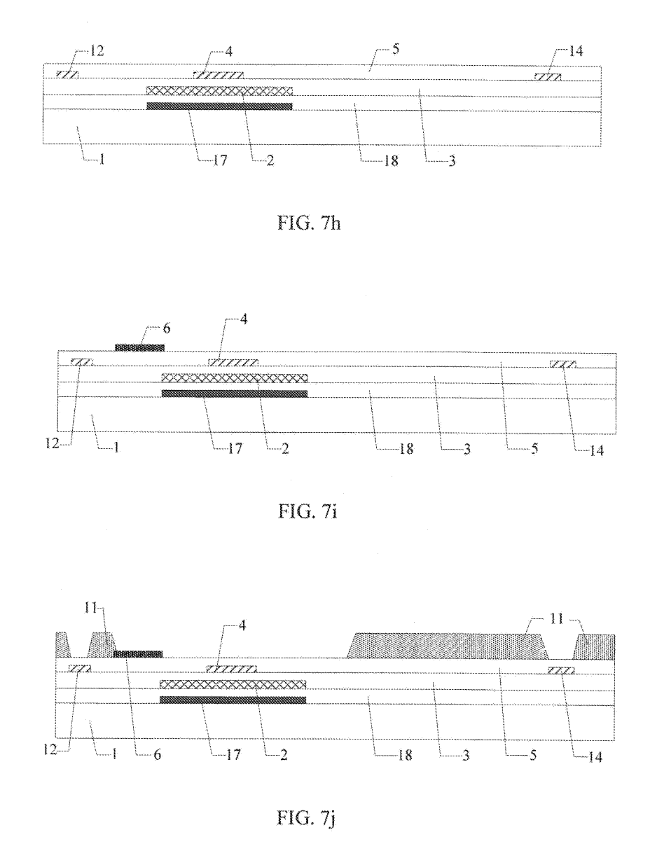

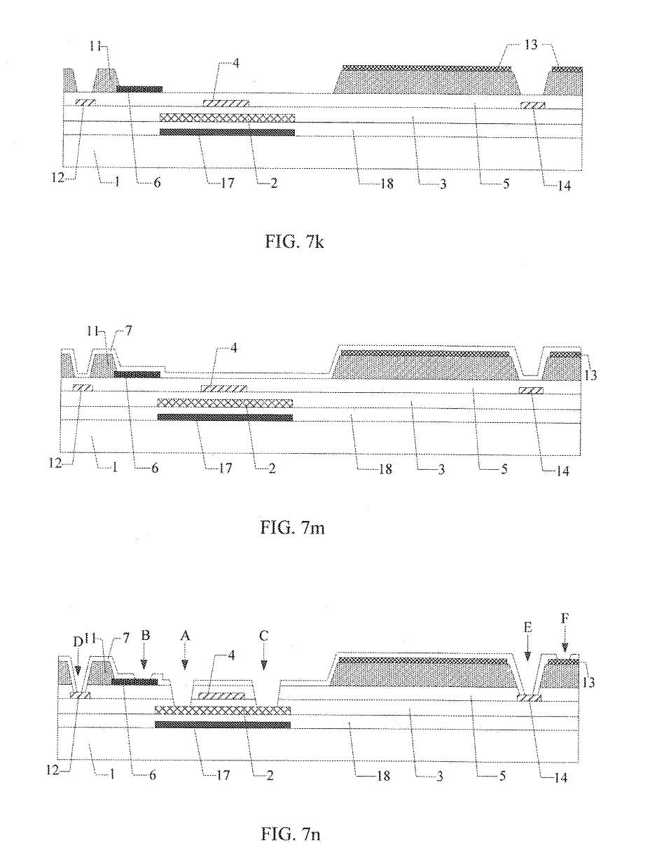

The manufacturing method of the array substrate illustrated in FIG. 2, as illustrated in FIG. 7a to FIG. 7k, FIG. 7m and FIG. 7n, may include the following steps.

1: forming a pattern of a light shielding layer 17 on a base substrate 1, as illustrated in FIG. 7a;

2: forming a buffer layer 18 on the base substrate 1 formed with the pattern of the light shielding layer 17, as illustrated in FIG. 7b;

3: forming an active layer thin film 19 by using an amorphous silicon material on the buffer layer 18, and performing an excimer laser annealing process on the active layer thin film 19, as illustrated in FIG. 7c;

4: patterning the active layer thin film 19 subjected to the excimer laser annealing process, to form a pattern of an active layer 2, as illustrated in FIG. 7d;

5: forming a gate insulating layer 3 on the base substrate 1 formed with the pattern of the active layer 2, as illustrated in FIG. 7e;

6: forming patterns including a gate electrode 4, a first wiring terminal 12 electrically connected with a gate line and a common electrode line 14 on the gate insulating layer 3, and reserving photoresist 20 located directly above the pattern of the gate electrode 4, as illustrated in FIG. 7f;

7: performing an N type heavily doping process on the pattern of the active layer 2 by using the photoresist 20 as a mask;

8: etching the photoresist 20, and performing an N type light doping process on the pattern of the active layer 2 by using the etched photoresist 20 as a mask, as illustrated in FIG. 7g;

9: forming a first insulating layer 5 after removing the remained photoresist 20, as illustrated in FIG. 7h;

10: forming a pattern including a source electrode 6 on the first insulating layer 5, as illustrated in FIG. 7i;

11: forming a pattern of a planarization layer 11 on the base substrate 1 formed with the pattern of the source electrode 6, as illustrated in FIG. 7j;

12: forming a pattern including a common electrode 13 on the base substrate formed with the pattern of the planarization layer 11, as illustrated in FIG. 7k;

13: forming a second insulating layer 7 on the base substrate 1 formed with the pattern of the source electrode 13, as illustrated in FIG. 7m;

14: forming a first via hole A, a second via hole B, a third via hole C, a fourth via hole D, a fifth via hole, a sixth via hole E and a seventh via hole F by a patterning process; wherein, the first via hole A passes through the second insulating layer 7, the first insulating layer 5 and the gate insulating layer 3 and is located in a region of the active layer 2 close to the source electrode 6, the second via hole B passes through the second insulating layer 7 and is located directly above the source electrode 6, the third via hole C passes through the second insulating layer 7, the first insulating layer 5 and the gate insulating layer 3 and is located in a region of the active layer 2 close to the pixel electrode 8 to be formed, the fourth via hole D passes through the second insulating layer 7, the planarization layer 11 and the first insulating layer 5 and is located directly above the first wiring terminal 12 electrically connected with the gate line, the fifth via hole passes through the second insulating layer and the planarization layer and is located directly above a second wiring terminal electrically connected with a data line, the sixth via hole E passes through the second insulating layer 7, the planarization layer 11 and the first insulating layer 5 and is located directly above the common electrode line 14, and the seventh via hole F passes through the second insulating layer 7 and is located directly above the common electrode 13, as illustrated in FIG. 7n;

15: forming patterns including a pixel electrode 8, a first connecting part 9, a second connecting part 10 and a third connecting part 15 on the base substrate 1 formed with the first via hole A, the second via hole B, the third via hole C, the fourth via hole D, the fifth via hole, the sixth via hole E and the seventh via hole F; wherein, the first connecting part 9 is electrically connected with the active layer 2 through the first via hole A, the first connecting part 9 is electrically connected with the source electrode 6 through the second via hole B, and the second connecting part 10 is electrically connected with the active layer 2 through the third via hole C; a PCB may be bonded with the first wiring terminal 12 through the fourth via hole D, and bonded with the second wiring terminal through the fifth via hole; the third connecting part 15 is electrically connected with the common electrode line 14 through the sixth via hole E, the third connecting part 15 is electrically connected with the common electrode 13 through the seventh via hole F; the second connecting part 10 is electrically connected with the pixel electrode 8, and the pixel electrode 8, the first connecting part 9 and the third connecting part 15 are insulated from each other, as illustrated in FIG. 2.

As for the array substrate, the manufacturing method thereof, the liquid crystal display panel and the display device provided by the embodiments of the present disclosure, in the manufacturing method of the array substrate, after forming the first insulating layer, before forming the source electrode, it is not necessary to form a via hole for electrically connecting the source electrode with the active layer by performing a patterning process; but after forming the second insulating layer, before forming the pixel electrode, the first via hole, the second via hole and the third via hole are formed by performing one patterning process, to expose the source electrode and the active layer; the source electrode and the active layer are electrically connected by using the first connecting part arranged on the same layer with the pixel electrode and insulated from the pixel electrode, the second connecting part arranged on the same layer with the pixel electrode and electrically connected with the pixel electrode is used as the drain electrode, and is electrically connected with the active layer through the third via hole, and in this way, as compared with an existing manufacturing method of an array substrate, one time of patterning process may be reduced, the fabrication process of the array substrate may be simplified, and moreover, an arrangement of the drain electrode may be saved, so that an aperture ratio of the array substrate may be increased.

The foregoing embodiments merely are exemplary embodiments of the present disclosure, and not intended to define the scope of the present disclosure, and the scope of the present disclosure is determined by the appended claims.

The present application claims priority of Chinese Patent Application No. 201510511403.7 filed on Aug. 19, 2015, the disclosure of which is incorporated herein by reference in its entirety as part of the present application.

1. An array substrate, comprising: a base substrate, an active layer, a gate insulating layer and a gate electrode which are located on the base substrate;
a first insulating layer, a source electrode, a second insulating layer and a pixel electrode which are sequentially stacked on the active layer, the gate insulating layer and the gate electrode; and
a first connecting part and a second connecting part arranged on a same layer with the pixel electrode; wherein,
the first connecting part is electrically connected with the active layer through a first via hole, the first connecting part is electrically connected with the source electrode through a second via hole, and the second connecting part is electrically connected with the active layer through a third via hole;
the second connecting part is electrically connected with the pixel electrode, and both the second connecting part and the pixel electrode are insulated from the first connecting part.

2. The array substrate according to claim 1, wherein, in a direction perpendicular to the base substrate, the active layer is located between the base substrate and the gate insulating layer, and the gate insulating layer is located between the active layer and the gate electrode;
the first via hole passes through the second insulating layer, the first insulating layer and the gate insulating layer, and is located in a region of the active layer close to the source electrode;
the second via hole passes through the second insulating layer, and is located directly above the source electrode;
the third via hole passes through the second insulating layer, the first insulating layer and the gate insulating layer, and is located in a region of the active layer close to the pixel electrode.

3. The array substrate according to claim 2, wherein, in a cross-section passing the first via hole, the third via hole and the gate electrode, the first via hole and the third via hole are located on both sides of the gate electrode, respectively.

4. The array substrate according to claim 1, wherein, the second connecting part and the pixel electrode are formed integrally.

5. The array substrate according to claim 1, wherein, the first connecting part and the second connecting part are in direct contact with the active layer.

6. The array substrate according to claim 2, further comprising: a planarization layer located between the source electrode and the second insulating layer;
at least a region of the planarization layer corresponding to the first connecting part and the second connecting part being a hollowed-out region.

7. The array substrate according to claim 6, further comprising:
a fourth via hole which passes through the second insulating layer, the planarization layer and the first insulating layer and is located directly above a first wiring terminal electrically connected with a gate line;
a fifth via hole which passes through the second insulating layer and the planarization layer and is located directly above a second wiring terminal electrically connected with a data line.

8. The array substrate according to claim 6, further comprising: a common electrode located between the planarization layer and the second insulating layer.

9. The array substrate according to claim 8, further comprising: a common electrode line electrically connected with the common electrode and arranged on a same layer with the gate electrode;
a third connecting part arranged on a same layer with the pixel electrode and insulated from the pixel electrode; wherein, the third connecting part is electrically connected with the common electrode line through a sixth via hole, the third connecting part is electrically connected with the common electrode through a seventh via hole, the sixth via hole passing through the second insulating layer, the planarization layer and the first insulating layer and being located directly above the common electrode line, and the seventh via hole passing through the second insulating layer and being located directly above the common electrode.

10. The array substrate according to claim 1, further comprising: a drain electrode arranged on a same layer with the source electrode, and an eighth via hole which passes through the second insulating layer and is located directly above the drain electrode;
the second connecting part being electrically connected with the drain electrode through the eighth via hole.

11. A liquid crystal display panel, comprising: an array substrate according to claim 1 and a counter substrate arranged opposite to the array substrate, and a liquid crystal layer located between the array substrate and the opposed substrate.

12. A display device, comprising: a liquid crystal display panel according to claim 11.

13. A manufacturing method of an array substrate, comprising:
forming patterns including an active layer, a gate insulating layer and a gate electrode on a base substrate;
forming a first insulating layer on the base substrate formed with the patterns of the active layer, the gate insulating layer and the gate electrode;
forming a pattern including a source electrode on the first insulating layer;
forming a second insulating layer on the base substrate formed with the pattern of the source electrode;
forming a first via hole, a second via hole and a third via hole by using a patterning process; and
forming patterns including a pixel electrode, a first connecting part and a second connecting part on the base substrate formed with the first via hole, the second via hole and the third via hole by using one patterning process; wherein, the first connecting part is electrically connected with the active layer through the first via hole, the first connecting part is electrically connected with the source electrode through the second via hole, and the second connecting part is electrically connected with the active layer through the third via hole, the second connecting part is electrically connected with the pixel electrode, and the second connecting part and the pixel electrode are insulated from the first connecting part.

14. The method according to claim 13, wherein, forming the patterns including the active layer, the gate insulating layer and the gate electrode on the base substrate, includes: forming the patterns including the active layer, the gate insulating layer and the gate electrode on the base substrate sequentially;
forming the first via hole, the second via hole and the third via hole, includes:
forming the first via hole which passes through the second insulating layer, the first insulating layer and the gate insulating layer and is located in a region of the active layer close to the source electrode, forming the second via hole which passes through the second insulating layer and is located directly above the source electrode, and forming the third via hole which passes through the second insulating layer, the first insulating layer and the gate insulating layer and is located in a region of the active layer close to the pixel electrode.

15. The method according to claim 14, wherein, after forming the pattern including the active layer, before forming the second insulating layer, the method further comprises:
forming a pattern including a planarization layer; wherein, at least a region of the pattern of the planarization layer corresponding to the first connecting part and the second connecting part is a hollowed-out region.

16. The method according to claim 15, wherein, simultaneously with forming the first via hole, the second via hole and the third via hole, the method further comprises:
forming a fourth via hole which passes through the second insulating layer, the planarization layer and the first insulating layer and is located directly above a first wiring terminal electrically connected with a gate line, and forming a fifth via hole which passes through the second insulating layer and the planarization layer and is located directly above a second wiring terminal electrically connected with a data line.

17. The method according to claim 15, wherein, after forming the pattern including the planarization layer, and before forming the second insulating layer, the method further comprises:
forming a pattern including a common electrode.

18. The method according to claim 17, wherein, a common electrode line electrically connected with the common electrode are arranged on a same layer with the gate electrode;
simultaneously with forming the first via hole, the second via hole and the third via hole, the method further comprises:
forming a sixth via hole which passes through the second insulating layer, the planarization layer and the first insulating layer and is located directly above the common electrode line, and forming a seventh via hole which passes through the second insulating layer and is located directly above the common electrode;
simultaneously with forming the pattern of the pixel electrode, the method further comprises:
forming a pattern including a third connecting part; wherein, the third connecting part is insulated from the pixel electrode, the third connecting part is electrically connected with the common electrode line through the sixth via hole, the third connecting part is electrically connected with the common electrode through the seventh via hole.

19. The method according to claim 13, wherein, simultaneously with forming the pattern of the source electrode, the method further comprises:
forming a pattern including a drain electrode;
simultaneously with forming the first via hole, the second via hole and the third via hole, the method further comprises:
forming an eighth via hole which passes through the second insulating layer and is located directly above the drain electrode; wherein, the second connecting part is electrically connected with the drain electrode through the eighth via hole.

20. The method according to claim 13, wherein, the second connecting part and the pixel electrode are formed integrally.
